(19) United States
(12) Patent Application Publication
(10) Pub. No.: US 2024/0309861 A1
(43) Pub. Date: Sep. 19, 2024

(54) EQUIPMENT PARAMETER RECOMMENDATION METHOD, ELECTRONIC DEVICE AND NON-TRANSITORY COMPUTER READABLE RECORDING MEDIUM

(71) Applicant: Wistron Corporation, New Taipei City (TW)

(72) Inventor: Chun-Hsien Li, New Taipei City (TW)

(73) Assignee: Wistron Corporation, New Taipei City (TW)

(21) Appl. No.: 18/322,574

(22) Filed: May 23, 2023

(30) Foreign Application Priority Data
Mar. 15, 2023 (TW) 112109634

(51) Int. Cl. F04D 27/00

(52) U.S. Cl. CPC F04D 27/001

(57) ABSTRACT

The disclosure provides an equipment parameter recommendation method, an electronic device and a non-transitory computer readable recording medium. Multiple feature variables associated with multiple air compressors are obtained according to equipment operation information of each of the air compressors. A predicted total displacement volume is obtained according to multiple feature variables associated with the air compressors and a production prediction model. A suggested equipment parameter of at least one of the air compressors is determined according to the predicted total displacement volume and an estimated maximum loading volume associated with the air compressors. Suggestion information associated with the suggested equipment parameter is displayed via the display.

### CROSS-REFERENCE TO RELATED APPLICATION

This application claims the priority benefit of Taiwan application serial no. 112109634, filed on Mar. 15, 2023. The entirety of the above-mentioned patent application is hereby incorporated by reference herein and made a part of this specification.

### BACKGROUND

### Technical Field

The disclosure relates to an energy-saving method, and particularly relates to an equipment parameter recommendation method, an electronic device and a non-transitory computer readable recording medium.

### Description of Related Art

Along with the increasingly important environmental issues of greenhouse gas reduction and energy-saving and carbon reduction, energy-saving has become one of the key development projects today. If it is able to effectively find out the causes of waste of electricity and provide an appropriate energy-saving method, it will not only contribute to environmental protection, but also greatly help cost-saving and profits of factories.

Equipment require power to maintain operations. Equipment with low energy efficiency need to consume more power to achieve operational goals, or even fail to function properly, resulting in waste of power. Generally, most of the factories have multiple equipment, but not all equipment needs to be turned on during a production process. Since each equipment has a different energy efficiency and equipment state, the choice of used equipment by an equipment manager will directly affect power cost and production efficiency. It is known that setting of equipment parameters of the equipment may also directly affect the power cost and production efficiency. However, a current group control system for the equipment in factory cannot provide suggestions on usage ranks and equipment parameters of the equipment, and professionals are generally required to conduct status inspections on each equipment to determine the equipment parameters of these equipment, and the equipment managers try to adjust the equipment parameters of the equipment to achieve the purpose of energy saving based on long-term accumulated personal subjective experiences. In other words, it is often not easy for the equipment managers to know how to adjust the equipment parameters of multiple equipment in the workplace to meet manufacturing needs and save electricity as much as possible.

### SUMMARY

Accordingly, the disclosure is directed to an equipment parameter recommendation method and an electronic device, which are adapted to solve the above technical problems.

An embodiment of the disclosure provides an equipment parameter recommendation method, which includes following steps. Multiple feature variables associated with multiple air compressors are generated according to equipment operation information of each of the air compressors. A predicted total displacement volume is obtained according to the feature variables associated with the air compressors and a production prediction model. A suggested equipment parameter of at least one of the air compressors is determined according to the predicted total displacement volume and an estimated maximum loading volume associated with the air compressors. Suggestion information associated with the suggested equipment parameter is displayed via a display.

An embodiment of the disclosure provides an electronic device including a display, a storage circuit, and a processor. The storage circuit stores multiple instructions. The processor is coupled to the display and the storage circuit, and accesses the instructions and is configured to execute the following steps. Multiple feature variables associated with multiple air compressors are generated according to equipment operation information of each of the air compressors. A predicted total displacement volume is obtained according to the feature variables associated with the air compressors and a production prediction model. A suggested equipment parameter of at least one of the air compressors is determined according to the predicted total displacement volume and an estimated maximum loading volume associated with the air compressors. Suggestion information associated with the suggested equipment parameter is displayed via the display.

An embodiment of the disclosure provides a computer readable recording medium storing a program, and when a computer loads and executes the program, the computer completes the above-mentioned equipment parameter recommendation method.

Based on the above description, in the embodiment of the disclosure, the predicted total displacement volume of the air compressors in an evaluation unit time period may be determined according to the equipment operation information of the air compressors and a trained machine learning model, and the suggested equipment parameter of at least one of the air compressors may be determined according to the predicted total displacement volume. Since the suggested equipment parameter may be configured based on the predicted total displacement volume and an energy saving principle, an equipment manager may easily know how to adjust the equipment parameters of the air compressors to effectively save electricity.

### BRIEF DESCRIPTION OF THE DRAWINGS

FIG. 1 is a schematic diagram of an electronic device according to an embodiment of the disclosure.

FIG. 2 is a flowchart of an equipment parameter recommendation method according to an embodiment of the disclosure.

FIG. 3 is a flowchart of an equipment parameter recommendation method according to an embodiment of the disclosure.

FIG. 4 is a flowchart of establishing the production prediction model according to an embodiment of the disclosure.

FIG. 5 is a flowchart of determining a suggested equipment parameter according to an embodiment of the disclosure.

FIG. 6 is a flowchart of determining a suggested equipment parameter according to an embodiment of the disclosure.

FIG. 7 is a schematic diagram illustrating a specific corresponding relationship of displacement volume and displacement pressure relative to electricity consumption according to an embodiment of the disclosure.

FIG. 8 is a schematic diagram of an operation interface of suggestion information according to an embodiment of the disclosure.

### DESCRIPTION OF THE EMBODIMENTS

Some embodiments of the invention will be described in detail with reference to the accompanying drawings. For the referenced element symbols in the following description, when the same element symbols appear in different drawings, they will be regarded as the same or similar elements. These embodiments are only a part of the invention, and do not reveal all possible implementation modes of the invention. Rather, these embodiments are merely examples of devices and methods within the claims of the invention.

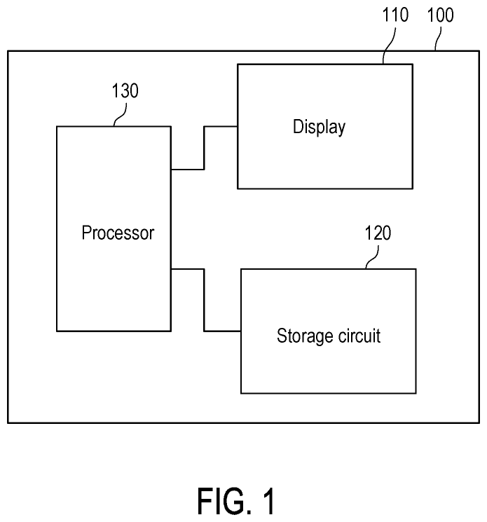

Referring to FIG. 1, FIG. 1 is a schematic diagram of an electronic device according to an embodiment of the disclosure. In different embodiments, an electronic device 100 is, for example, a computer device such as a notebook computer, a desktop computer, a server, and a workstation, etc., with computing capabilities, but the disclosure is not limited thereto. The electronic device 100 may include a display 110, a storage circuit 120, and a processor 130.

The display 110 is, for example, various types of display such as a liquid crystal display (LCD), a light emitting diode (LED) display, an organic light emitting diode (OLED) display, etc., that is built in the electronic device 100, but the disclosure is not limited thereto. In other embodiments, the display 110 may also be any display device externally connected to the electronic device 100.

The storage circuit 120 is, for example, any type of a fixed or removable random access memory (RAM), a read-only memory (ROM), a flash memory, a hard disk or other similar device, or a combination of these devices, which may be used to record multiple instructions, program codes, or software modules.

The processor 130 is, for example, a central processing unit (central processing unit (CPU), an application processor (AP), or other programmable general purpose or special purpose microprocessor, digital signal processor (DSP), image signal processor (ISP), graphics processing unit (GPU) or other similar devices, integrated circuits and combinations thereof. The processor 130 may access and execute software modules recorded in the storage circuit 120 to implement the equipment recommendation method of the embodiment of the disclosure. The above-mentioned software modules may be broadly interpreted as meaning instructions, instruction sets, codes, program codes, programs, applications, software packages, threads, procedures, functions, etc., regardless of whether they are referred to as software, firmware, intermediate software, microcode, hardware description languages, or others.

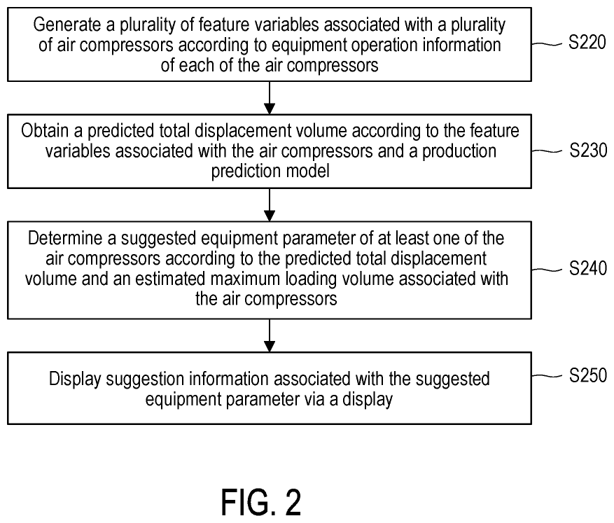

FIG. 2 is a flowchart of an equipment parameter recommendation method according to an embodiment of the disclosure. Referring to FIG. 1 and FIG. 2, the method of the embodiment is applicable to the electronic device 100 of the above-mentioned embodiment, and detailed steps of the equipment parameter recommendation method of the embodiment will be described below with reference of various components in the electronic device 100.

In some embodiments, the processor 130 may obtain equipment operation information of each of multiple air compressors. In some embodiments, these air compressors may provide power by exhausting air, so as to drive transportation equipment or pneumatic devices, etc. The equipment operation information of the air compressors may include electricity consumption data, equipment status data or equipment output data, etc. The equipment operation information of the air compressors may be obtained by sensors or measuring instruments by performing sensing and measurement operations. The above-mentioned sensors or measuring instruments may include electric meters, thermometers, hygrometers, pressure gauges, etc., which is not limited by the disclosure. Alternatively, the equipment operation information of the air compressors may be obtained from a product production plan or a factory production log recorded in the storage circuit 120. The electricity consumption data may include electricity consumption per unit time period or statistical electricity consumption, etc. The equipment status data may include displacement pressure, displacement temperature or idling state, etc. The equipment output data may include displacement volume per unit time period. Herein, the electronic device 100 may determine suggested equipment parameters for one or more air compressors in a workplace, but specifications and models of these air compressors may be the same or different. In addition, the equipment operation information of the air compressors may further include product production line information, such as a product production volume, etc.

In step S220, the processor 130 may generate multiple feature variables associated with the air compressors according to the equipment operation information of each of the air compressors. In some embodiments, according to the equipment operation information of the air compressors in multiple previous unit time periods, the processor 130 may obtain multiple feature variables corresponding to the previous unit time periods and associated with the air compressors.

In some embodiments, the feature variables generated according to the equipment operation information of three previous unit time periods are taken as an example for description. The processor 130 may obtain displacement temperatures of each of the air compressors in the three previous unit time periods (for example, the previous one hour, the previous two hours and the previous three hours). Then, the processor 130 may perform an average operation on the displacement temperatures of all air compressors in a certain previous unit time period (for example, the previous one hour) to obtain a feature variable corresponding to the previous unit time period (for example, the previous one hour). Deduced by analogy, by calculating the average displacement temperatures of the air compressors in the other two previous unit time periods (for example, the previous two hours and the previous three hours), the processor 130 may then obtain other two feature variables corresponding to the other two previous unit time periods. According to the same principle, the processor 130 may perform average operations on the displacement pressures and equipment energy efficiencies of the air compressors in the previous unit time periods to generate multiple feature variables corresponding to the previous unit time periods.

In some embodiments, the processor 130 may determine equipment energy efficiency of the air compressor according to the equipment operation information. The equipment energy efficiency of the air compressor may represent equipment operation efficiency under the unit electricity consumption. In some embodiments, the processor 130 obtains a displacement volume of the air compressor in the previous unit time period from the equipment operation information, and determines the equipment energy efficiency according to a ratio of the displacement volume in the previous unit time period to the electricity consumption of the air compressor in the same previous unit time period. A time length of the unit time period may be one day, half a day, two hours or one hour, etc., which is not limited in the disclosure.

In some embodiments, the feature variables generated according to the equipment operation information of three previous unit time periods are taken as an example for description. The processor 130 may obtain displacement volumes of each of the air compressors in the three previous unit time periods (for example, the previous one hour, the previous two hours and the previous three hours). Then, the processor 130 may sum up the displacement volumes of all air compressors in a previous unit time period (for example, the previous one hour) to obtain a feature variable corresponding to the previous unit time period (for example, the previous one hour). Deduced by analogy, by calculating a total displacement volume of the air compressors in the other two previous unit time periods (for example, the previous two hours and the previous three hours), the processor 130 may then obtain other two feature variables corresponding to the other two previous unit time periods. In addition, according to the same principle, the processor 130 may perform a sum operation according to the electricity consumption per unit time period of each air compressor in each of the previous unit time periods to generate multiple feature variables respectively corresponding to the previous unit time periods.

In some embodiments, the feature variables generated according to the equipment operation information of three previous unit time periods are taken as an example for description. The processor 130 may determine whether each air compressor operates in an idling state during the three previous unit time periods (for example, the previous one hour, the previous two hours, and the previous three hours). The idling state represents a state in which the air compressor has no load but still consumes electricity. In other words, an operating state in which an air storage chamber of the air compressor has sufficient pressure or there is no output air but a motor continues to run may be referred to as the idling state. Then, the processor 130 may count the number of idling air compressors operating in the idling state within the previous unit time period (for example, the previous one hour) to obtain a feature variable corresponding to the previous unit time period (for example, the previous one hour). Deduced by analogy, by determining the numbers of idling air compressors in the other two previous unit time periods (such as the previous two hours and the previous three hours), the processor 130 may then obtain other two feature variables corresponding to the other two previous unit time periods.

In some embodiments, the feature variables generated according to the equipment operation information of three previous unit time periods are taken as an example for description. The processor 130 may obtain a product output of the three previous unit time periods, so as to obtain the three feature variables respectively corresponding to the three previous unit time periods.

In some embodiments, the feature variables generated according to the equipment operation information of three previous unit time periods are taken as an example for description. The processor 130 may obtain a displacement volume of each air compressor in the three previous unit time periods (for example, the previous one hour, the previous two hours, and the previous three hours). Then, the processor 130 may calculate a difference in the displacement volumes between a first previous unit time period and a second previous unit time period (for example, the previous one hour and the previous two hours) to obtain a feature variable. Moreover, the processor 130 may calculate a difference in the displacement volumes between the second previous unit time period and a third previous unit time period (for example, the previous two hours and the previous three hours) to obtain another feature variable.

In step S230, the processor 130 may obtain a predicted total displacement volume according to the feature variables associated with the air compressors and a production prediction model. The production prediction model is a machine learning model. The production prediction model may generate the predicted total displacement volume of the air compressors according to an input feature variable. The processor 130 may input the feature variables associated with the air compressors and corresponding to the previous unit time periods into the production prediction model to generate the predicted total displacement volume. In addition, the processor 130 may use the production prediction model to obtain the predicted total displacement volume corresponding to an evaluation unit time period according to the feature variables corresponding to the previous unit time periods before the evaluation unit time period.

In more detail, the processor 130 may establish the production prediction model according to the equipment operation information of the air compressors, and the production prediction model trained based on the machine learning algorithm may be recorded in the storage circuit 120. In other words, the processor 130 may perform machine learning by taking the equipment operation information of a past period of time as a training data set to create the production prediction model for predicting the predicted total displacement volume of multiple air compressors in an evaluation unit time period according to the input feature variable.

In step S240, the processor 130 may determine a suggested equipment parameter of at least one of the air compressors according to the predicted total displacement volume and an estimated maximum loading volume associated with the air compressors. The estimated maximum loading volume may be a preset value or generated according to the equipment operation information of the air compressors. To be specific, when the predicted total displacement volume is greater than the estimated maximum loading volume, it represents that the equipment parameters of some or all of the air compressors need to be adjusted to increase the total displacement volume of these air compressors. Therefore, in some embodiments, by comparing the predicted total displacement volume with the estimated maximum loading volume, the processor 130 may determine and generate suggested equipment parameters for all air compressors according to the predicted total displacement volume. When the predicted total displacement volume is less than or equal to the estimated maximum loading volume, it means that it may not be necessary to turn on all the air compressors to provide sufficient displacement volume. Therefore, in some embodiments, by comparing the predicted total displacement volume with the estimated maximum loading volume, the processor 130 may decide to select the activated air compressors from these air compressors, so as to use a part of the air compressors to complete tasks. In addition, in some embodiments, the processor 130 may determine the suggested equipment parameters of the activated air compressors according to the predicted total displacement volume.

In step S250, the processor 130 may display suggestion information associated with the suggested device parameters via the display 110. Namely, the processor 130 may provide the suggested information associated with the suggested equipment parameters through the display 110, so that the equipment manager may adjust the equipment parameters of the air compressors according to the suggested information associated with the suggested equipment parameters. In some embodiments, the suggested information may include the suggested equipment parameter of each air compressor. In some embodiments, the suggestion information may include electricity saving benefit information generated by applying the suggested device parameters. In this way, the equipment manager may control the operations of the air compressors according to the suggested information, so as to avoid waste of unnecessary electricity by the air compressors to reduce energy waste.

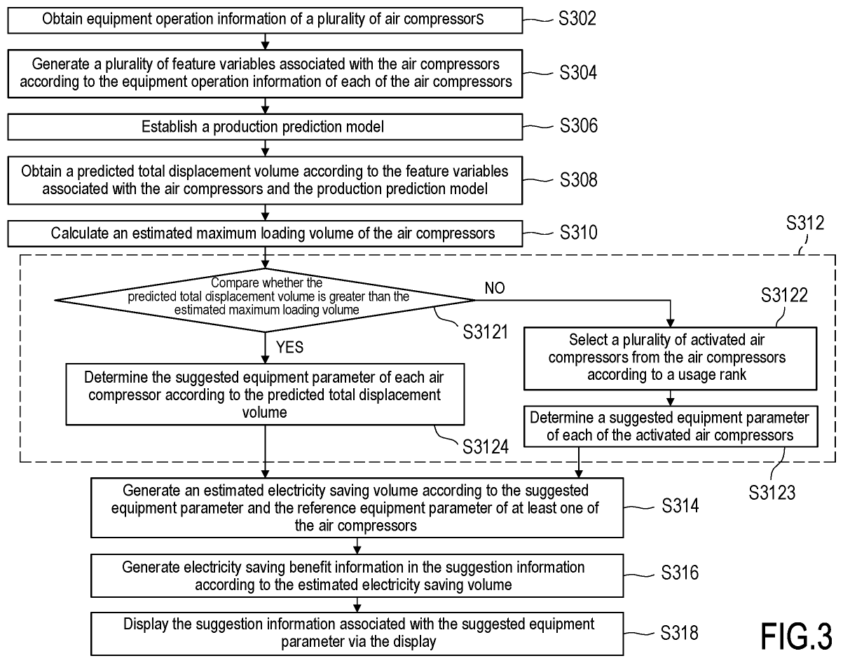

FIG. 3 is a flowchart of an equipment parameter recommendation method according to an embodiment of the disclosure. Referring to FIG. 1 and FIG. 3, the method of this embodiment is applicable to the electronic device 100 in the above-mentioned embodiment, and the detailed steps of the equipment parameter recommendation method of the embodiment will be described below with reference of various components in the electronic device 100.

In step S302, the processor 130 may obtain equipment operation information of multiple air compressors. In step S304, the processor 130 may generate multiple feature variables associated with the air compressors according to the equipment operation information of each of the air compressors. For detailed operations of steps S302 to S304, reference may be made to the description of the steps S210-S220 of the embodiment in FIG. 2, and details thereof are not repeated here.

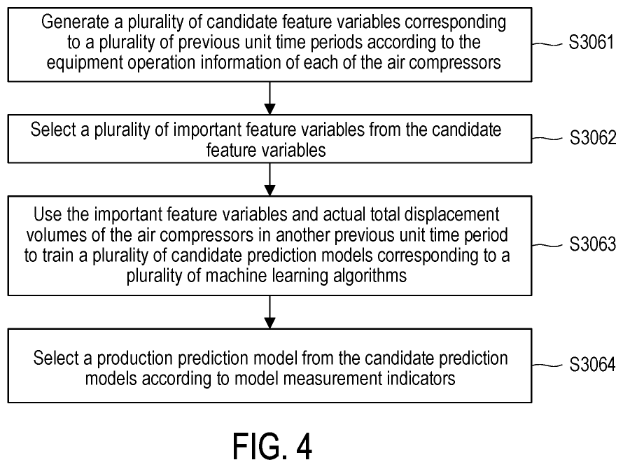

In step S306, the processor 130 may establish a production prediction model. It should be noted that the disclosure does not limit a training timing of the production prediction model, and the sequence of steps shown in FIG. 3 is only for demonstration. The production prediction model only needs to be established before it is applied to predict the predicted total displacement volume. Referring to FIG. 4, FIG. 4 is a flowchart of establishing the production prediction model according to an embodiment of the disclosure. In the embodiment of FIG. 4, step S306 may be implemented as steps S3061 to S3064.

In step S3061, the processor 130 may generate multiple candidate feature variables corresponding to multiple previous unit time periods according to the equipment operation information of each of the air compressors. In detail, the processor 130 may collect the equipment operation information of multiple previous unit time periods in the past period of time. Then, the processor 130 may generate the candidate feature variables corresponding to the previous unit time periods according to the equipment operation information of the previous unit time periods based on many different feature extraction methods. These candidate feature variables are input information of the machine learning model. For the method of generating the candidate feature variables corresponding to the previous unit time periods, reference may be made to the content of obtaining the feature variables above, and details thereof will not be repeated.

For example, taking generation of multiple candidate feature variables based on equipment operation information of three previous unit time periods as an example, table 1 lists the candidate feature variables corresponding to the three previous unit time periods.

TABLE 1

| | Average total | Average total | Average | Average |
|---|---|---|---|---|
| Previous unit | displacement | electricity | displacement | displacement |
| time period | volume | consumption | pressure | temperature |
| 2023 Jan. 8 | Candidate | Candidate | Candidate | Candidate |
| 16:00~17:00 | feature | feature | feature | feature |
| | variable # 1 | variable # 4 | variable # 7 | variable # 10 |
| 2023 Jan. 8 | Candidate | Candidate | Candidate | Candidate |
| 15:00~16:00 | feature | feature | feature | feature |
| | variable # 2 | variable # 5 | variable # 8 | variable # 11 |
| 2023 Jan. 8 | Candidate | Candidate | Candidate | Candidate |
| 14:00~15:00 | feature | feature | feature | feature |
| | variable # 3 | variable # 6 | variable # 9 | variable # 12 |
| | Average | Number of | | Change of total |
| Previous unit | energy | idling | | displacement |
| time period | efficiency | equipment | Product output | volume |
| 2023 Jan. 8 | Candidate | Candidate | Candidate | Candidate |
| 16:00~17:00 | feature | feature | feature | feature |
| | variable # 13 | variable # 16 | variable # 19 | variable # 22 |
| 2023 Jan. 8 | Candidate | Candidate | Candidate | Candidate |
| 15:00~16:00 | feature | feature | feature | feature |
| | variable # 14 | variable # 17 | variable # 20 | variable # 23 |
| 2023 Jan. 8 | Candidate | Candidate | Candidate | |
| 16:00~17:00 | feature | feature | feature | |
| | variable # 15 | variable # 18 | variable # 21 | |

However, the disclosure is not limited to the three previous unit time periods, which is just an example. In other embodiments, the processor 130 may retrieve candidate feature variables corresponding to other numbers of previous unit time periods. In the example of table 1, the processor 130 may generate 23 candidate feature variables corresponding to three previous unit time periods, and the change of the total displacement volume (i.e., the candidate feature variable #22 and the candidate feature variable #23) is a difference between the total displacement volumes of two adjacent previous unit time periods.

Then, in step S3062, the processor 130 may select multiple important feature variables from the candidate feature variables. In some embodiments, the processor 130 may select the important feature variables from the candidate feature variables based on feature selection algorithms in feature engineering. These feature selection algorithms may include a stepwise method. Alternatively, these feature selection algorithms may include a feature selection method of feature weight based on a support vector regression (SVR) algorithm or feature usage times based on a random forest algorithm. To select multiple important feature variables may reduce complexity and a computation load of a training model. Correspondingly, to input multiple associated important feature variables when using the model may also reduce a computation time. In other embodiments, in the case of sufficient computing resources, this step may be ignored, and all of the candidate feature variables may be used to perform subsequent steps.

In step S3063, the processor 130 may use the important feature variables and actual total displacement volumes of the air compressors in another previous unit time period to train multiple candidate prediction models corresponding to multiple machine learning algorithms. It should be noted that, during the model training process, ground truths used for training the candidate prediction models are the actual total displacement volumes of the another previous unit time period. For example, if the description is continued with reference of the example shown in table 1, the processor 130 may use the actual total displacement volumes of the air compressors in another previous unit time period (i.e., from 17:00 to 18:00 on January 8) as the ground truths required for model training. The machine learning algorithm used to train the production prediction model may include but not limited to the random forest algorithm, a linear regression algorithm, a long short-term memory (LSTM) algorithm, and/or autoregressive integrated moving average model (ARIMA). However, the machine learning algorithm used to train the production prediction model is not limited by the disclosure, which may be set according to an actual application.

Each candidate prediction model is trained based on the important feature variables and one of the machine learning algorithms. To be specific, the processor 130 may use the important feature variables to train a candidate prediction model according to a first machine learning algorithm, and use the important feature variables to train another candidate predictive model according to a second machine learning algorithm.

In step S3064, the processor 130 may select a production prediction model from the candidate prediction models according to model measurement indicators. Specifically, the processor 130 may use model test data to respectively test the candidate prediction models to generate the model measurement indicator corresponding to each candidate prediction model. The above model test data is, for example, historical equipment operation information and historical total displacement volumes, and the above model measurement indicator is, for example, mean absolute error (MAE) or mean absolute percentage error (MAPE), but the disclosure is not limited thereto. In some embodiments, the processor 130 may compare the model measurement indicator of each candidate prediction model, and select the candidate prediction model with the smallest model measurement indicator as the final production prediction model.

Referring to FIG. 3, in step S308, the processor 130 may obtain a predicted total displacement volume according to the feature variables associated with the air compressors and the production prediction model. In detail, based on the important feature variables determined during a model building period, the processor 130 may obtain multiple corresponding feature variables according to the equipment operation information in multiple previous unit time periods, and input the feature variables corresponding to the previous unit time periods into the production prediction model to predict the predicted total displacement volume of the unit time period.

For example, the processor 130 may extract multiple feature variables corresponding to three previous unit time periods “14:00-17:00, March 1st” from the equipment operation information of the air compressors, and input these feature variables into the production prediction model, so that the production prediction model outputs the predicted total displacement volume corresponding to the evaluation unit time period “17:00-18:00, March 1”.

In step S310, the processor 130 may calculate an estimated maximum loading volume of the air compressors. In some embodiments, the processor 130 may calculate a maximum unit loading volume of each air compressor according to the historical displacement volumes of each air compressor in multiple previous unit time periods and idling information of each air compressor. Then, the processor 130 may obtain the estimated maximum loading volume by summing up the maximum unit loading volumes of the air compressors. Namely, the processor 130 may first determine the maximum unit loading volume of each air compressor according to the historical displacement volumes of each of the air compressors in the previous unit time periods, and then estimate the estimated maximum loading volume jointly generated by the multiple air compressors.

It should be particularly noted that, in some embodiments, in response to determining that a first air compressor in the air compressors is in the idling state in a first previous unit time period in the previous unit time periods, the processor 130 may calculate an expected maximum displacement volume of the first air compressor in the first previous unit time period according to an idling rate of the first air compressor and one of the historical displacement volumes of the first air compressor in the first previous unit time period. Since the idling state may reduce the displacement volume of the air compressor, the processor 130 may increase the historical displacement volume of the first air compressor operating in the idling state in a certain previous unit time period to the expected maximum displacement volume through this step. Then, the processor 130 may determine the maximum unit loading volume of the first air compressor in the previous unit time periods by comparing the expected maximum displacement volume with the historical displacement volumes in the previous unit time periods or multiple expected maximum displacement volumes in the previous unit time periods of the first air compressor.

For example, table 2 lists the historical displacement volume and idling state of four air compressors in multiple previous unit time periods. Moreover, table 2 further lists the idling rates respectively corresponding to each of the four air compressors. Where, “*” in table 2 indicates the idling time period that is determined to be in the idling state.

TABLE 2

| | | Historical | Historical | Historical | |
|---|---|---|---|---|---|
| | | displacement | displacement | displacement | |
| | | volume of | volume of | volume of | |
| | Current | previous one | previous two | previous three | Idling |
| Equipment | time | hour | hours | hours | rate |
| 1# | 15:00 | 2500 | 2400* | 2450 | 0.01 |
| 2# | 15:00 | 550 | 530 | 520* | 0.05 |
| 3# | 15:00 | 2400 | 2360* | 2440 | 0.02 |
| 4# | 15:00 | 1450 | 1430 | 1420* | 0.02 |

Thus, when the air compressor 1 # appeared the idling state in the previous two hours, the processor 130 may calculate the expected maximum displacement volume “2424” of the previous two hours according to the idling rate “0.01” of the air compressor 1 # and the historical displacement volume “2400” of the air compressor 1 # of the previous two hours. Where, the expected maximum displacement volume “2424” is equal to the historical displacement volume “2400” multiplied by (1+0.01). Similarly, when the air compressor 2 # appeared the idling state in the previous three hours, the processor 130 may calculate the expected maximum displacement volume “546” of the previous three hours according to the idling rate “0.05” of the air compressor 2 # and the historical displacement volume “520” of the air compressor 2 # of the previous three hours. Where, the expected maximum displacement volume “546” is equal to the historical displacement volume “520” multiplied by (1+0.05). And the others may be deduced by analogy. Taking table 2 as an example, the processor 130 may obtain the expected maximum displacement volumes of each air compressor in different previous unit time periods, which may be shown in table 3. It should be noted that during a non-idling time period, the expected maximum displacement volume of each air compressor is the historical displacement volume.

TABLE 3

| | | Expected | Expected | Expected |
|---|---|---|---|---|
| | | maximum | maximum | maximum |
| | | displacement | displacement | displacement |
| | | volume of | volume of | volume of |
| | Current | previous one | previous two | previous three |
| Equipment | time | hour | hours | hours |
| 1# | 15:00 | 2500 | 2424 | 2450 |
| 2# | 15:00 | 550 | 530 | 546 |
| 3# | 15:00 | 2400 | 2407 | 2440 |
| 4# | 15:00 | 1440 | 1430 | 1448 |

Thereafter, taking table 3 as an example to continue the description, the processor 130 may select the maximum unit loading volume of each air compressor according to the expected maximum displacement volumes of each air compressor, which is shown in table 4.

TABLE 4

| | | Maximum unit |
|---|---|---|
| Equipment | Current time | loading volume |
| 1# | 15:00 | 2500 |
| 2# | 15:00 | 550 |
| 3# | 15:00 | 2440 |
| 4# | 15:00 | 1440 |

Thereafter, by summing up the maximum unit loading volume of each air compressor, the processor 130 may obtain the estimated maximum loading volume of the air compressors. Taking table 4 as an example, the processor 130 may obtain the estimated maximum loading volume of the four air compressors 1 # to 4 # as 2500+550+2440+1440-6930 (cubic meters).

In some embodiments, the processor 130 may calculate the idling rate of the first air compressor according to idling hours of the first air compressor within a statistical time period. In detail, the processor 130 may first determine whether an operating state corresponding to the previous unit time periods is the idling state. Then, the processor 130 may calculate the idling rate of the first air compressor according to a number of idling time periods in the previous unit time periods. Here, a time length of the previous unit time period for estimating the idling rate may be one day, half a day, one hour, or 30 minutes, etc., which is not limited in the disclosure. Furthermore, in some embodiments, the processor 130 may calculate an idling time within the statistical time period. The idling time represents a total length of time that the equipment is operated in the idling state during the statistical time period. Thereafter, the processor 130 may calculate the idling rate according to the idling time and the statistical time period. The statistical time period may be one week, three days, one day or half a day, etc., which is not limited in the disclosure. For example, taking a length of the previous unit time period of one hour as an example, the processor 130 may calculate a ratio of a total length of the idling time period of a certain air compressor equipment in the idling state to the statistical time period in the past 60 days (i.e., the statistical time period) to obtain the idling rate of the air compressor. Detection of the idling state may be implemented according to the displacement volume and electricity consumption of the air compressor.

Thereafter, in step S312, the processor 130 may determine a suggested equipment parameter of at least one of the air compressors according to the predicted total displacement volume and the estimated maximum loading volume. In the embodiment, step S312 may be implemented as step S3121 to step S3124.

In step S3121, the processor 130 may compare the predicted total displacement volume with the estimated maximum loading volume to determine whether the predicted total displacement volume is greater than the estimated maximum loading volume. If the determination result of step S3121 is negative, in step S3122, the processor 130 may select multiple activated air compressors from the air compressors according to a usage rank in response to the fact that the predicted total displacement volume is less than or equal to the estimated maximum loading volume. Specifically, when the predicted total displacement volume is less than or equal to the estimated maximum loading volume, it means that it may not be necessary to turn on all of the air compressors. Therefore, the processor 130 may select the activated air compressors from the air compressors according to the usage rank, the predicted total displacement volume and the maximum unit loading volume of each air compressor, so as to meet the condition that a sum of the maximum unit loading volumes of multiple activated air compressors is greater than or equal to the predicted total displacement volume.

Then, in step S3123, the processor 130 determines a suggested equipment parameter of each of the activated air compressors. In some embodiments, since the activated air compressors are determined according to the equipment operation information of the previous unit time period, the suggested equipment parameters of the activated air compressors may be equipment parameters applied to the previous unit time period. In other words, the suggested equipment parameters of the activated air compressors are maintained to the equipment parameters used in the previous unit time period.

Taking table 4 as an example to continue the description, it is assumed that the predicted total displacement volume produced by the production prediction model is 5000 cubic meters, it means that the predicted total displacement volume is less than the estimated maximum loading volume “6930 cubic meters”. In this case, it is assumed that the usage rank of the air compressor 1 # is 1; the usage rank of the air compressor 2 # is 4; the usage rank of the air compressor 3 # is 3; and the usage rank of the air compressor 4 # is 2. The processor 130 may select the air compressor 1 #, the air compressor 4 #, and the air compressor 3 # as the activated air compressors according to the usage rank, so as to meet the condition that the sum of the maximum unit loading volumes of the air compressor 1 #, the air compressor 3 #, and the air compressor 4# is greater than the predicted total displacement volume of “5000 cubic meters”.

In some embodiments, the usage ranks of these air compressors may be determined according to one or more usage rank indicators, and these usage rank indicators may include equipment energy efficiency, idling rate, availability, production compliance rate, equipment age, usage frequency or a combination thereof. In some embodiments, the processor 130 may determine the usage rank of each air compressor by inputting the usage rank indicator of each air compressor into the machine learning model. In some embodiments, the processor 130 may determine the usage rank of each air compressor by respectively sorting or weighting the usage rank indicators of each of the air compressors. In other embodiments, the processor 130 may sort the equipment energy efficiencies to determine the usage rank of each air compressor.

In addition, if the determination result of step S3121 is affirmative, in step S3124, the processor 130 may determine the suggested equipment parameter of each air compressor according to the predicted total displacement volume in response to the predicted total displacement volume being greater than the estimated maximum loading volume. In detail, in some embodiments, the processor 130 may distribute the additionally increased displacement volume to all of the air compressors for outputting according to an output loading ratio of the air compressors. Alternatively, in some embodiments, the processor 130 may distribute the additionally increased displacement volume to the least number of air compressors for outputting. Examples will be provided below for description. In addition, for clarity's sake, in the following embodiment, a suggested displacement pressure is taken as the suggested equipment parameter for description. By changing the displacement pressure of the air compressor, the displacement volume of the air compressor may be adjusted.

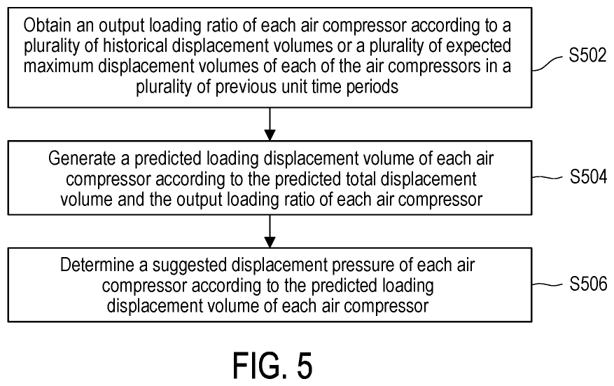

Referring to FIG. 5, FIG. 5 is a flowchart of determining a suggested equipment parameter according to an embodiment of the disclosure. In the embodiment shown in FIG. 5, step S3124 may be implemented as steps S502 to S506, and the processor 130 may configure the suggested displacement pressures of all of the air compressors according to the output loading ratios of the air compressors.

In step S502, the processor 130 obtains the output loading ratio of each air compressor according to the historical displacement volumes or the expected maximum displacement volumes of each of the air compressors in the previous unit time periods. In some embodiments, taking table 2 as an example to continue the description, the processor 130 may first determine an equipment loading ratio of each air compressor in each of the previous unit time periods, as shown in table 5 below. Further, the processor 130 may respectively divide the displacement volume of each air compressor in each previous unit time period by the sum of the displacement volumes of the air compressors in each previous unit time period to obtain the equipment loading ratio of each air compressor in each previous unit time period. Taking the air compressor 1 # in table 2 as an example, the equipment loading ratio of the air compressor 1 # in the previous one hour is equal to the historical displacement volume of the air compressor 1 # in the previous one hour divided by the sum of the historical displacement volumes of the four air compressors 1 #-4 #, which is 0.36=2500/(2500+550+2400+1450).

TABLE 5

| | | Equipment | Equipment | Equipment |
|---|---|---|---|---|
| | | loading ratio | loading ratio | loading ratio |
| | Current | of previous | of previous | of previous |
| Equipment | time | one hour | two hours | three hours |
| 1# | 15:00 | 0.36 | 0.36 | 0.36 |
| 2# | 15:00 | 0.08 | 0.07 | 0.07 |
| 3# | 15:00 | 0.35 | 0.35 | 0.36 |
| 4# | 15:00 | 0.21 | 0.22 | 0.21 |

Then, the processor 130 may perform a weighting operation on the equipment loading ratios of each air compressor in different previous unit time periods to generate the output loading ratio of each air compressor. For example, the processor 130 may perform the weighting operation on the equipment loading ratios 0.36, 0.36, and 0.36 of the air compressor 1 # in the first three previous unit time periods to generate the output loading ratio of each air compressor. For example, weight values corresponding to the first three previous unit time periods may be 0.4, 0.3, and 0.3 respectively, so that the output loading ratio of the air compressor 1 # is 0.36*0.4+0.36*0.3+0.36*0.3=0.36.

It should be noted that in some embodiments, the processor 130 may establish a linear regression model by taking the actual total displacement volume of the air compressors in the previous unit time periods as an input variable and using the actual total displacement volume in an evaluation unit time period as an output variable. The processor 130 may use the historical displacement volumes of the air compressors in the past period of time (for example, 60 days) to establish a linear regression model. These previous unit time periods and the evaluation unit time period may be consecutive time periods, and the previous unit time period is earlier than the evaluation unit time period. Then, the processor 130 may use multiple coefficients in the linear regression model as multiple weight values respectively corresponding to the previous unit time periods. For example, the linear regression model may be characterized as: the total displacement volume of the evaluation unit time period=0.4*the total displacement volume of the previous one hour+0.3*the total displacement volume of the previous two hours+0.3*the total displacement volume of the previous three hours. Taking table 5 as an example and the weight values of 0.4, 0.3, and 0.3 as an example to continue the description, the processor 130 may obtain the output loading ratios shown in table 6.

TABLE 6

| | Current | |
|---|---|---|
| Equipment | time | Output loading ratio |
| 1# | 15:00 | 0.36 = 0.36*0.4 + 0.36*0.3 + 0.36*0.3 |
| 2# | 15:00 | 0.074 |
| 3# | 15:00 | 0.353 |
| 4# | 15:00 | 0.213 |

Then, in step S504, the processor 130 generates the predicted loading displacement volume of each air compressor according to the predicted total displacement volume and the output loading ratio of each air compressor. To be specific, the processor 130 may multiply the predicted total displacement volume by the output loading ratio of each air compressor to generate the predicted loading displacement volume of each air compressor. Taking table 6 as an example and it is assumed that the predicted total displacement volume is 7000, the processor 130 may obtain the predicted loading displacement volumes as shown in table 7.

TABLE 7

| | Current | Predicted loading displacement volume |
|---|---|---|
| Equipment | time | (cubic meter) |
| 1# | 15:00 | 7000*0.36 = 2520 |
| 2# | 15:00 | 7000*0.074 = 518 |
| 3# | 15:00 | 7000*0.353 = 2471 |
| 4# | 15:00 | 7000*0.213 = 1491 |

In step S506, the processor 130 determines a suggested displacement pressure of each air compressor according to the predicted loading displacement volume of each air compressor. It is known that the displacement pressure of the air compressor has a specific corresponding relationship with the displacement volume. More specifically, to reduce the displacement pressure may increase the displacement volume of the air compressor. For example, for a certain air compressor, to reduce the displacement pressure by 1 bar may increase the displacement volume by 5% and reduce the electricity consumption by 5%. The specific corresponding relationship between the displacement pressure and the displacement volume of the air compressor may be established according to tests. Namely, the processor 130 may deduce the suggested displacement pressure of each air compressor under the condition of knowing how much the displacement volume of each air compressor needs to be increased.

It is assumed that a reference displacement pressure of each air compressor in the previous unit time period is 8 bar, taking table 4 and table 7 as an example, the processor 130 may obtain a displacement volume increase ratio shown in table 8, and calculate the suggested displacement pressure according to the specific corresponding relationship between the displacement pressure and the displacement volume (i.e., to reduce the displacement pressure by 1 bar may increase the displacement volume by 5%).

TABLE 8

| | | | Suggested |
|---|---|---|---|
| | | | displacement |
| | Current | Displacement volume | pressure |
| Equipment | time | increase ratio | (bar) |
| 1# | 15:00 | 2520/2500-1 = 0.008 | 7.84 |
| 2# | 15:00 | 518/550-1 = −0.058 | 8 |
| 3# | 15:00 | 2471/2440-1 = 0.013 | 7.74 |
| 4# | 15:00 | 1491/1440-1 = 0.035 | 7.3 |

It should be noted that for the air compressor 2 # in table 8, if the displacement volume is reduced to increase the displacement pressure, the electricity consumption is also increased. Therefore, in the example, the processor 130 may decide to maintain the suggested displacement volume of the air compressor 2 # at 8 bar. However, the specific corresponding relationship between the displacement pressure and the displacement volume used in the above example is only an exemplary description, and is not intended to limit the disclosure, which may be set according to an actual state of the air compressor.

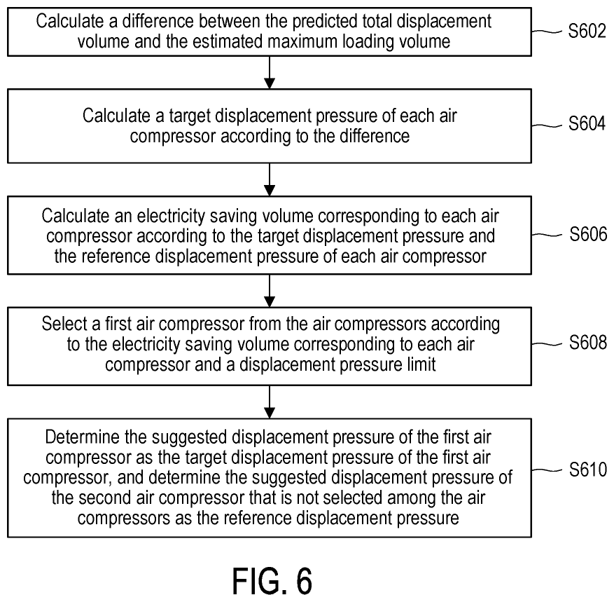

Referring to FIG. 6, FIG. 6 is a flowchart of determining a suggested equipment parameter according to an embodiment of the disclosure. In the embodiment of FIG. 6, step S3124 may be implemented as steps S602 to S610, and the processor 130 may configure the suggested displacement pressures of all of the air compressors based on the principle of adjusting the least number of the air compressors.

In step S602, the processor 130 calculates a difference between the predicted total displacement volume and the estimated maximum loading volume. In step S604, the processor 130 calculates a target displacement pressure of each air compressor according to the difference. In detail, the processor 130 may first calculate a target displacement volume of each air compressor according to the difference between the predicted total displacement volume and the estimated maximum loading volume. Then, the processor 130 may obtain the target displacement pressure of each air compressor according to the target displacement volume of each air compressor.

For example, taking table 4 as an example, it is assumed that the predicted total displacement volume is 7000 and the estimated maximum loading volume is 6930, the processor 130 may obtain a difference of 7000−6930=70 cubic meters. A target displacement volume of the air compressor 3 # is 2440+70=2510. A target displacement volume of the air compressor 1 # is 2500+70=2570. A target displacement volume of the air compressor 2 # is 550+70=620. A target displacement volume of the air compressor 4 # is 1440+70=1510. Thereafter, according to the specific corresponding relationship between the displacement volume and the displacement pressure of each air compressor, the processor 130 may derive the target displacement pressure of each air compressor according to the above-mentioned target displacement volume of each air compressor.

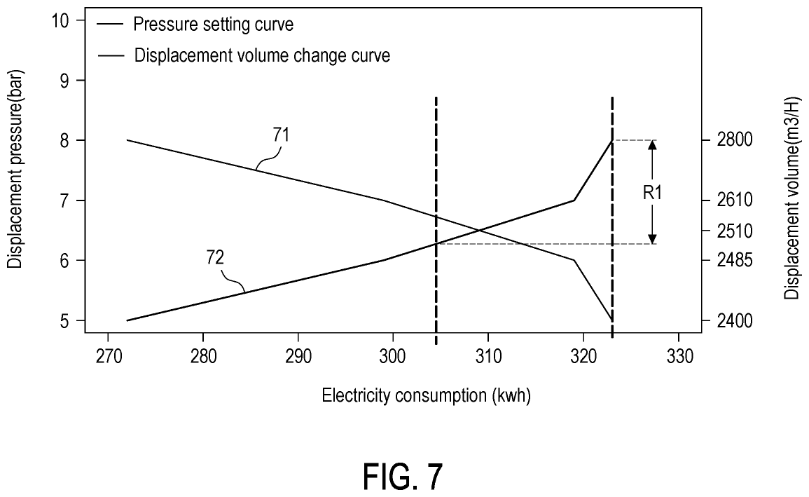

For example, FIG. 7 is a schematic diagram illustrating a specific corresponding relationship of displacement volume and displacement pressure relative to electricity consumption according to an embodiment of the disclosure. A displacement volume change curve 71 and a pressure setting curve 72 shown in FIG. 7 may be established by testing and experimenting with air compressors. In addition, the displacement pressure of each air compressor needs to be within a certain limit range R1. For example, each air compressor needs to have a minimum displacement pressure of 6 bar, otherwise the air compressor will not be able to smoothly drive a transportation equipment or pneumatic equipment in the workplace. According to the displacement volume change curve 71 and the pressure setting curve 72 shown in FIG. 7, the processor 130 may correspondingly obtain a target displacement pressure according to the target displacement volume of each air compressor.

Then, in step S606, the processor 130 calculates an electricity saving volume corresponding to each air compressor according to the target displacement pressure and the reference displacement pressure of each air compressor. The reference displacement pressure may be a displacement pressure applied by each air compressor in a previous time period. According to the specific corresponding relationship between the displacement volumes, the displacement pressures and the electricity consumption (such as shown in FIG. 7), the processor 130 may use the target displacement pressure to obtain corresponding first electricity consumption, and use the reference displacement pressure to obtain corresponding second electricity consumption. Therefore, the processor 130 may calculate a difference between the first electricity consumption and the second electricity consumption as the electricity saving volume. For example, the processor 130 may obtain the electricity saving volume shown in table 9 below.

TABLE 9

| | Reference | Target | |
|---|---|---|---|
| | displacement | displacement | Electricity saving |
| Equipment | pressure (bar) | pressure (bar) | volume (Kwh) |
| 1# | 8 | 7.5 | 20 |
| 2# | 7.5 | 7 | 10 |
| 3# | 8 | 6.2 | 32 |
| 4# | 7 | 5.8 | 35 |

Then, in step S608, the processor 130 selects a first air compressor from the air compressors according to the electricity saving volume corresponding to each air compressor and a displacement pressure limit. In step S610, the processor 130 determines the suggested displacement pressure of the first air compressor as the target displacement pressure of the first air compressor, and determines the suggested displacement pressure of the second air compressor that is not selected among the air compressors as the reference displacement pressure.

In detail, taking the displacement pressure limit as the displacement pressure cannot be less than 6 bar as an example, only the air compressor 1 #, the air compressor 2 #, and the air compressor 3 # comply with the displacement pressure limit. The processor 130 compares the electricity saving volumes of the air compressor 1 #, the air compressor 2 #, and the air compressor 3 #, and selects the air compressor 3 #(i.e., the first air compressor) from the air compressors 1 #-4 #. In other words, under the principle of adjusting the least number of the air compressors, the processor 130 may select to adjust the displacement pressure of the air compressor 3 #. Moreover, the suggested displacement pressure of the air compressor 3 # is the target displacement pressure of the air compressor 3 #, while the suggested displacement pressures of the other unselected air compressor 1 #, air compressor 2 #, air compressor 4 #(i.e., the second air compressor) may be maintained at the reference displacement pressure. Taking table 9 as an example, in the case of selecting to adjust the displacement pressure of the air compressor 3 #, the processor 130 may obtain the suggested displacement pressures shown in table 10.

TABLE 10

| | Suggested displacement |
|---|---|
| Equipment | pressure (bar) |
| 1# | 8 |
| 2# | 7.5 |
| 3# | 6.2 |
| 4# | 7 |

Referring back to FIG. 3 again, after obtaining the suggested displacement pressures of the air compressors according to the above description, step S314 is executed. In step S314, the processor 130 may generate an estimated electricity saving volume according to the suggested equipment parameter and the reference equipment parameter of at least one of the air compressors. The suggested equipment parameter and the reference equipment parameter may be respectively the suggested displacement pressure and the reference displacement pressure. By referring to the specific corresponding relationship between the displacement pressure and the electricity consumption as shown in FIG. 7, the processor 130 may generate an estimated electricity saving volume according to the suggested displacement pressure and the reference displacement pressure of each air compressor. In step S316, the processor 130 may generate electricity saving benefit information in the suggestion information according to the estimated electricity saving volume. In some embodiments, the processor 130 may multiply the estimated electricity saving volume by an operating time of the air compressor and a unit price of electricity to generate the electricity saving benefit information.

Taking table 9 and table 10 as an example to continue the description, the processor 130 may obtain the estimated electricity saving volume (i.e., 20 Kwh) according to the suggested displacement pressure of the air compressor 3 # and the reference displacement pressure of the previous time period. Then, the processor 130 may multiply the estimated electricity saving volume of the air compressor 3 # by an operating time of the air compressor 3 # and the unit price of electricity to generate the electricity saving benefit information. Namely, the electricity saving benefit information includes electricity cost that may be saved by lowering the displacement pressure of the air compressor 3 # to the suggested displacement pressure.

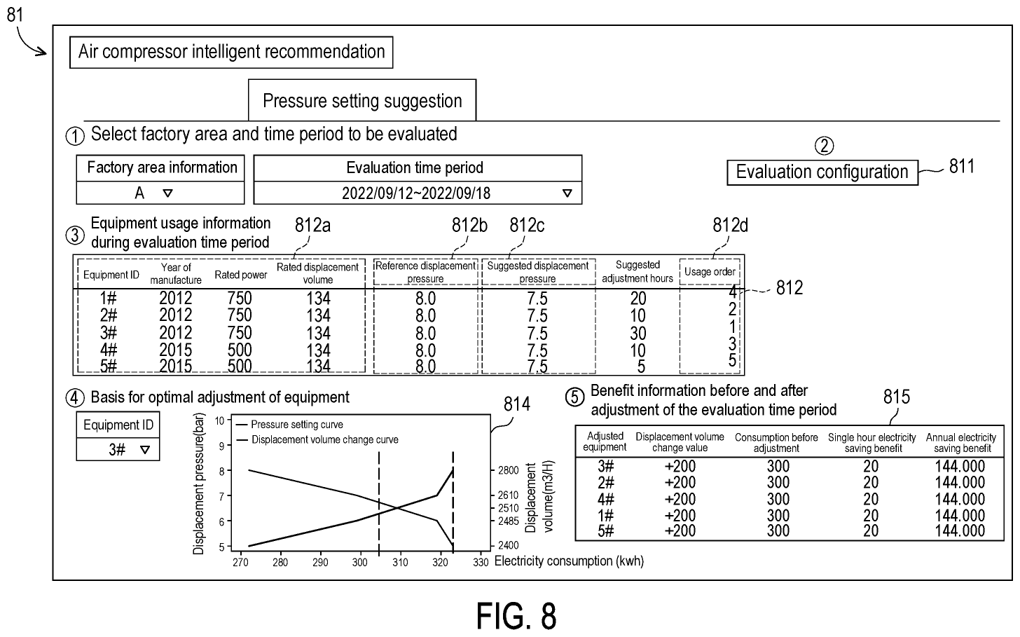

Finally, in step S318, the processor 130 may display the suggestion information associated with the suggested equipment parameter via the display 110. For example, FIG. 8 is a schematic diagram of an operation interface of suggestion information according to an embodiment of the disclosure. Referring to FIG. 8, the display 110 may display an equipment recommendation interface 81. A manager may click an option 811 of the equipment recommendation interface 81 to trigger the operation that the processor 130 generates the suggestion information associated with the suggested equipment parameter according to the aforementioned embodiment, and display the suggestion information on the equipment recommendation interface 81.

A field 812 includes equipment data 812a, reference displacement pressures 812b, suggested displacement pressures 812c, and suggested adjustment sequence 812d of the air compressor. A field 814 includes the specific corresponding relationship between the displacement volume, displacement pressure and electricity consumption of the air compressor 3 #. A field 815 includes the electricity saving benefit information generated by respectively taking each air compressor as an adjustment target.

In an embodiment of the disclosure, a non-transitory computer-readable recording medium is also provided. The non-transitory computer-readable recording medium stores a program, and when a computer loads the program and executes the same, the technical contents of the above-mentioned embodiments are completed.

The processing procedure of the equipment parameter recommendation method executed by at least one processor is not limited to the examples of the above-mentioned embodiments. For example, a part of the steps (processing) described above may be omitted, and each step may be performed in another order. In addition, any two or more of the above steps may be combined, and a part of the steps may be corrected or deleted. Alternatively, other steps may also be performed in addition to the above steps.

In summary, in the embodiment of the disclosure, the predicted total displacement volume of the air compressors may be obtained according to the equipment operation information of the air compressors and the trained machine learning model, and the suggested equipment parameter of at least one of the air compressors may be determined according to the predicted total displacement volume. Since the suggested equipment parameter may be configured based on the predicted total displacement volume and an energy saving principle, an equipment manager may easily know how to adjust the equipment parameters of the air compressors to effectively save electricity, and may plan a parameter adjustment method of the air compressors in advance. Based on this, electricity may be effectively saved and manufacturing cost may be reduced while meeting the requirements of a production environment.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. An equipment parameter recommendation method, comprising:
generating a plurality of feature variables associated with a plurality of air compressors according to equipment operation information of each of the air compressors;
obtaining a predicted total displacement volume according to the feature variables associated with the air compressors and a production prediction model;
determining a suggested equipment parameter of at least one of the air compressors according to the predicted total displacement volume and an estimated maximum loading volume associated with the air compressors; and
displaying suggestion information associated with the suggested equipment parameter via a display.

2. The equipment parameter recommendation method according to claim 1, further comprising:
generating a plurality of candidate feature variables corresponding to a plurality of previous unit time periods according to the equipment operation information of each of the air compressors;
selecting a plurality of important feature variables from the candidate feature variables;
using the important feature variables and an actual total displacement volume of the air compressors in another previous unit time period to train a plurality of candidate prediction models corresponding to a plurality of machine learning algorithms; and
selecting the production prediction model from the candidate prediction models according to a model measurement indicator, wherein the production prediction model is a machine learning model.

3. The equipment parameter recommendation method according to claim 1, further comprising:
calculating a maximum unit loading volume of each of the air compressors according to a plurality of historical displacement volumes of each of the air compressors in a plurality of previous unit time periods and idling information of each of the air compressors; and
obtaining the estimated maximum loading volume by summing up the maximum unit loading volume of each of the air compressors.

4. The equipment parameter recommendation method according to claim 3, wherein the step of calculating the maximum unit loading volume of each of the air compressors according to the historical displacement volumes of each of the air compressors in the previous unit time periods and the idling information of each of the air compressors comprises:
calculating an expected maximum displacement volume of a first air compressor in a first previous unit time period according to an idling rate of the first air compressor and one of the historical displacement volumes of the first air compressor in the first previous unit time period in response to determining that the first air compressor among the air compressors is in an idling state in the first previous unit time period in the previous unit time periods; and
determining the maximum unit loading volume of the first air compressor in the previous unit time periods by comparing the expected maximum displacement volume with the historical displacement volumes in the previous unit time periods or a plurality of expected maximum displacement volumes in the previous unit time periods of the first air compressor.

5. The equipment parameter recommendation method according to claim 4, wherein the step of calculating the maximum unit loading volume of each of the air compressors according to the historical displacement volumes of each of the air compressors in the previous unit time periods and the idling information of each of the air compressors further comprises:
calculating the idling rate of the first air compressor according to an idling hour of the first air compressor within a statistical time period.

6. The equipment parameter recommendation method according to claim 1, wherein the step of determining the suggested equipment parameter of at least one of the air compressors according to the predicted total displacement volume and the estimated maximum loading volume comprises:
comparing the predicted total displacement volume with the estimated maximum loading volume; and
determining the suggested equipment parameter of each of the air compressors according to the predicted total displacement volume in response to the predicted total displacement volume being greater than the estimated maximum loading volume.

7. The equipment parameter recommendation method according to claim 6, wherein the suggested equipment parameter comprises a suggested displacement pressure, and the step of determining the suggested equipment parameter of each of the air compressors according to the predicted total displacement volume in response to the predicted total displacement volume being greater than the estimated maximum loading volume comprises:
obtaining an output loading ratio of each of the air compressors according to a plurality of historical displacement volumes or a plurality of expected maximum displacement volumes of each of the air compressors in a plurality of previous unit time periods;
generating a predicted loading displacement volume of each of the air compressors according to the predicted total displacement volume and the output loading ratio of each of the air compressors; and
determining the suggested displacement pressure of each of the air compressors according to the predicted loading displacement volume of each of the air compressors.

8. The equipment parameter recommendation method according to claim 6, wherein the suggested equipment parameter comprises a suggested displacement pressure, and the step of determining the suggested equipment parameter of each of the air compressors according to the predicted total displacement volume in response to the predicted total displacement volume being greater than the estimated maximum loading volume comprises:
calculating a difference between the predicted total displacement volume and the estimated maximum loading volume;
calculating a target displacement pressure of each of the air compressors according to the difference;
calculating an electricity saving volume corresponding to each of the air compressors according to the target displacement pressure of each of the air compressors and a reference displacement pressure of each of the air compressors;
selecting a first air compressor from the air compressors according to the electricity saving volume corresponding to each of the air compressors and a displacement pressure limit; and
determining the suggested displacement pressure of the first air compressor as the target displacement pressure of the first air compressor, and determining the suggested displacement pressure of a second air pressure that is not selected among the air compressors as the reference displacement pressure.

9. The equipment parameter recommendation method according to claim 1, wherein the step of determining the suggested equipment parameter of at least one of the air compressors according to the predicted total displacement volume and the estimated maximum loading volume comprises:
comparing the predicted total displacement volume with the estimated maximum loading volume;
selecting a plurality of activated air compressors from the air compressors according to a usage rank in response to the predicted total displacement volume being less than the estimated maximum loading volume; and
determining the suggested equipment parameter of each of the activated air compressors.

10. The equipment parameter recommendation method according to claim 1, further comprising:
generating an estimated electricity saving volume according to the suggested equipment parameter of at least one of the air compressors and a reference equipment parameter of the at least one of the air compressors; and
generating electricity saving benefit information in the suggestion information according to the estimated electricity saving volume.

11. An electronic device, comprises:
a display;
a storage circuit, storing a plurality of instructions; and
a processor, coupled to the display and the storage circuit and accessing the instructions to execute:
generating a plurality of feature variables associated with a plurality of air compressors according to equipment operation information of each of the air compressors;
obtaining a predicted total displacement volume according to the feature variables associated with the air compressors and a production prediction model;
determining a suggested equipment parameter of at least one of the air compressors according to the predicted total displacement volume and an estimated maximum loading volume associated with the air compressors; and
displaying suggestion information associated with the suggested equipment parameter via the display.

12. The electronic device according to claim 11, wherein the processor further executes:
generating a plurality of candidate feature variables corresponding to a plurality of previous unit time periods according to equipment operation information of each of the air compressors;
selecting a plurality of important feature variables from the candidate feature variables;
using the important feature variables and an actual total displacement volume of the air compressors in another previous unit time period to train a plurality of candidate prediction models corresponding to a plurality of machine learning algorithms; and
selecting the production prediction model from the candidate prediction models according to a model measurement indicator, wherein the production prediction model is a machine learning model.

13. The electronic device according to claim 11, wherein the processor further executes:
calculating a maximum unit loading volume of each of the air compressors according to a plurality of historical displacement volumes of each of the air compressors in a plurality of previous unit time periods and idling information of each of the air compressors; and
obtaining the estimated maximum loading volume by summing up the maximum unit loading volume of each of the air compressors.

14. The electronic device according to claim 13, wherein the processor further executes:
calculating an expected maximum displacement volume of a first air compressor in a first previous unit time period according to an idling rate of the first air compressor and one of the historical displacement volumes of the first air compressor in the first previous unit time period in response to determining that the first air compressor among the air compressors is in an idling state in the first previous unit time period in the previous unit time periods; and
determining the maximum unit loading volume of the first air compressor in the previous unit time periods by comparing the expected maximum displacement volume with the historical displacement volumes in the previous unit time periods or a plurality of expected maximum displacement volumes in the previous unit time periods of the first air compressor.

15. The electronic device according to claim 11, wherein the processor further executes:
comparing the predicted total displacement volume with the estimated maximum loading volume; and
determining the suggested equipment parameter of each of the air compressors according to the predicted total displacement volume in response to the predicted total displacement volume being greater than the estimated maximum loading volume.

16. The electronic device according to claim 15, wherein the suggested equipment parameter comprises a suggested displacement pressure, and the processor further executes:
obtaining an output loading ratio of each of the air compressors according to a plurality of historical displacement volumes or a plurality of expected maximum displacement volumes of each of the air compressors in a plurality of previous unit time periods;
generating a predicted loading displacement volume of each of the air compressors according to the predicted total displacement volume and the output loading ratio of each of the air compressors; and
determining the suggested displacement pressure of each of the air compressors according to the predicted loading displacement volume of each of the air compressors.

17. The electronic device according to claim 15, wherein the suggested equipment parameter comprises a suggested displacement pressure, and the processor further executes:
calculating a difference between the predicted total displacement volume and the estimated maximum loading volume;
calculating a target displacement pressure of each of the air compressors according to the difference;
calculating an electricity saving volume corresponding to each of the air compressors according to the target displacement pressure of each of the air compressors and a reference displacement pressure of each of the air compressors;
selecting a first air compressor from the air compressors according to the electricity saving volume corresponding to each of the air compressors and a displacement pressure limit; and
determining the suggested displacement pressure of the first air compressor as the target displacement pressure of the first air compressor, and determining the suggested displacement pressure of a second air pressure that is not selected among the air compressors as the reference displacement pressure.

18. The electronic device according to claim 11, wherein the processor further executes:
comparing the predicted total displacement volume with the estimated maximum loading volume;
selecting a plurality of activated air compressors from the air compressors according to a usage rank in response to the predicted total displacement volume being less than the estimated maximum loading volume; and
determining the suggested equipment parameter of each of the activated air compressors.

19. The electronic device according to claim 11, wherein the processor further executes:
generating an estimated electricity saving volume according to the suggested equipment parameter of at least one of the air compressors and a reference equipment parameter of the at least one of the air compressors; and
generating electricity saving benefit information in the suggestion information according to the estimated electricity saving volume.

20. A computer readable recording medium, storing a program, and a computer loading the program to execute: generating a plurality of feature variables associated with a plurality of air compressors according to equipment operation information of each of the air compressors; obtaining a predicted total displacement volume according to the feature variables associated with the air compressors and a production prediction model; determining a suggested equipment parameter of at least one of the air compressors according to the predicted total displacement volume and an estimated maximum loading volume associated with the air compressors; and displaying suggestion information associated with the suggested equipment parameter.
